(19) United States
(12) Patent Application Publication
(10) Pub. No.: US 2025/0046605 A1
(43) Pub. Date: Feb. 6, 2025

(54) SUBSTRATE PROCESSING METHOD

(71) Applicant: ASM IP Holding B.V., Almere (NL)

(72) Inventor: Wataru Adachi, Kawasaki-shi (JP)

(21) Appl. No.: 18/788,490

(22) Filed: Jul. 30, 2024

Related U.S. Application Data
(60) Provisional application No. 63/530,301, filed on Aug. 2, 2023.

(51) Int. Cl. H01L 21/02; C23C 16/40; C23C 16/455; C23C 16/56

(52) U.S. Cl. CPC H01L 21/02274; C23C 16/401; C23C 16/45536; C23C 16/45553; C23C 16/56; H01L 21/02164; H01L 21/02211

(57) ABSTRACT

Provided is a method for forming a low-k film by PEALD. In one embodiment, a first silicon precursor is supplied, followed by a second silicon precursor in order to form a silicon precursor layers. Then oxidant is supplied to form a silicon oxide film. The method further comprises a post treatment in order to remove a moisture from the film. The method according to the disclosure enables to form a silicon oxide film with desired low-k value and good step coverage on the recess structure.

### CROSS-REFERENCE TO RELATED APPLICATIONS

This application claims priority to U.S. Provisional Patent Application Ser. No. 63/530,301 filed Aug. 2, 2023 and titled SUBSTRATE PROCESSING METHOD, the disclosure of which is hereby incorporated by reference in its entirety.

### FIELD OF INVENTION

The disclosure relates to a method for forming a low-k film on a substrate, particularly to a method for forming a low-k film in a recess by a plasma enhanced atomic layer deposition (PEALD) method.

### BACKGROUND OF THE DISCLOSURE

As the critical dimension (CD) of a semiconductor device shrinks, electrical interference between material layers consisting of a circuit of the device increases. The electrical interference (e.g., electrical resistance) in the circuit causes a RC (Resistance-Capacitance) delay arising from an insulating layer and becomes one of main causes of slow response time of the semiconductor device. To lower the RC delay in the circuit, a film with low-k value (i.e., a film with low dielectric constant) such as SiO, SiOC and SiOCH has been introduced.

A low-k film is used for the liner application of TSV (Through Silicon Via) process in which a low-k film is thinly formed conformally along the surface of the recess area such as via between forming a metal layer. The low-k film with k-value less than 3.9 is obtained by a conventional plasma enhanced chemical vapor deposition (PECVD) method. For instance, SiO₂ or SiN or a combination thereof may be used as a liner layer for low-k film. But as the critical dimension of the semiconductor device continues to shrink, uniformity of the film deposited in a recess structure becomes poor. For instance, an overhang at the upper portion of the recess may occur in the PECVD process, resulting in the non-conformal film adversely affecting the k-value (i.e., dielectric constant) of the film. In addition, as the devices continues to shrink, a film with lower k-value is required (e.g., 3.5 or less).

FIG. 1 illustrates a film deposition along the surface of the recess by a conventional PECVD method. FIG. 1 may be a part of TSV process in which a low-k film such as SiO₂ or SiN may be formed as a liner on the wall of the recess, followed by forming a barrier film such as Ta/TaN on it, filling the recess with copper and planarizing the substrate from the top and from the bottom of the substrate. In FIG. 1, the PECVD process shows a high film growth rate, but it results in a non-conformal film deposition along the surface (e.g., overhang in the upper region of the gap).

Therefore, conformally forming a film with low-k value of 3.5 or less along the surface of the recess structure is required.

### SUMMARY OF THE DISCLOSURE

The disclosure discloses a method for forming a film having a good step coverage feature along the gap structure as well as low-k value in a narrow gap structure. Specifically, the disclosure discloses a PEALD method for forming a low-k film by supplying multiple precursors.

In one or more embodiments, a method for forming the low-k film comprises the steps of supplying a first silicon precursors to the reactor, supplying a second silicon precursor and supplying an oxidant to the reactor. And the steps are cyclically repeated a plurality of times to form a silicon oxide film.

In one or more embodiments, the first silicon precursor may comprise a reactive group comprising an alkylamine and a non-reactive group comprising an alkyl group and a hydrogen group, and the second silicon precursor may comprise a reactive group comprising an alkylamine and a non-reactive group comprising a hydrogen group.

In one or more embodiments, the first silicon precursor may be an organosilane-containing amine and the second silicon precursor may be an aminosilane.

In one or more embodiments, the first silicon precursor may comprise at least one of (Dimethylamino)trimethylsilane, Bis(dimethylamino)dimethylsilane, N,N-dimethyl-2,4,6,8-tetramethyl-cyclotetrasiloxan-2-amine, N,N-diethyl-2,4,6,8-tetramethyl-cyclotetrasiloxan-2-amine, or a combination thereof.

In one or more embodiments, the second precursor may comprise at least one of DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; DIPAS, SiH₃N(iPr)₂; 3DMAS, SiH(N(Me)₂)₃; BEMAS, SiH₂[N(Et)(Me)]₂; TEMS, SiH(NEtMe)₃; TIPAS, SiH(NHiPr)₃; BDIPADS, (N(iPr)₂)SiH₂—SiH₂(N(iPr)₂); BDEADS, (NEt₂)SiH₂—SiH₂(NEt₂); BDPADS, (NPr₂)SiH₂—SiH₂(NPr₂); or a combination thereof.

In one or more embodiments, the oxidant may comprise at least one of oxygen plasma, CO₂ plasma, N₂O plasma, ozone, or a combination thereof.

In one or more embodiments, the method further comprises supplying a hydrogen-containing gas throughout the steps.

In one or more embodiments, the method further comprises carrying out a post treatment to remove moisture from the silicon oxide film.

In one or more embodiments, the post treatment may be carried out by thermal treatment and at least one of plasma treatment, UV treatment, VUV treatment, or a combination thereof.

In one or more embodiments, the plasma post treatment may be carried out by supplying at least one of: an argon plasma, a helium plasma, a hydrogen plasma, or a combination thereof.

In one or more embodiments, a dielectric constant of the silicon oxide film formed by the method may be 3.5 or less.

In one or more embodiments, a film growth rate of the silicon oxide film may be 0.1 nm per cycle or greater.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a film deposition along the surface of the recess by a conventional PECVD method.

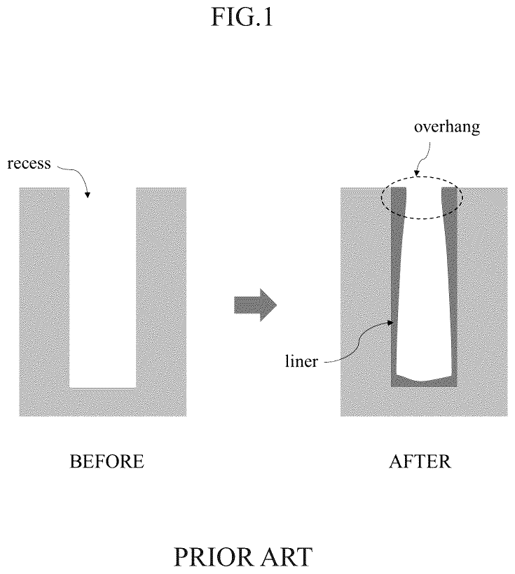

FIG. 2 illustrates a process flow for forming a low-k film using the method.

FIG. 3 illustrates a timing graph for the process of FIG. 2.

FIG. 4 illustrates another process flow for forming a low-k film using the method.

FIG. 5 illustrates a timing graph for the process of FIG. 4.

FIG. 6 illustrates a film-forming mechanism in accordance with the method.

FIG. 7 illustrates a film structure before and after a post treatment.

FIG. 8 shows a FT-IR Absorbance graph showing a film composition before post treatment in accordance with a process condition.

FIG. 9 shows a TEM photo of low-k film formed on the sidewall of the gap in TSV device using the method.

FIG. 10 illustrates a TSV process to which an embodiment of the disclosure may be applied.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

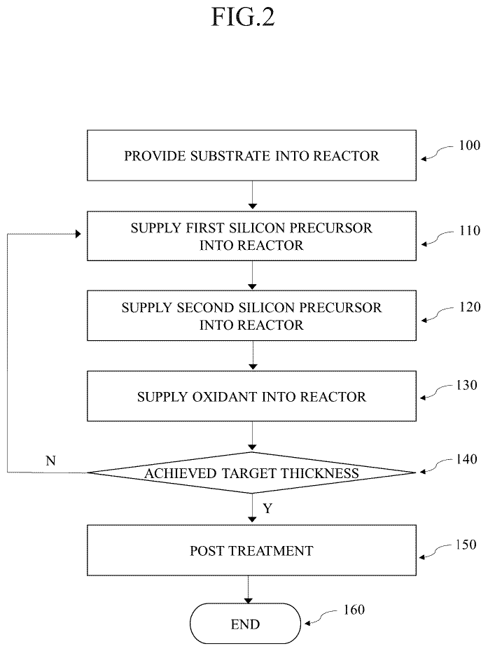

FIG. 2 illustrates a process flow for forming a low-k film using the method. Each step of the process flow will be described in more detail below.

In step 100 of FIG. 2, a substrate is provided into a reactor. The substrate may include a recess structure such as a gap, 3D device structure and a through-hole penetrating the substrate. The substrate may be loaded onto a substrate support such as susceptor. The susceptor may be a part of heating block supplying a heat energy to the susceptor.

In step 110, a first silicon precursor is supplied into the reactor. The first silicon precursor may adsorb onto the reactive sites formed on the surface of the substrate. For instance, the first silicon precursor may adsorb conformally onto the surface along the gap structure.

The first silicon precursor may contain a reactive group comprising an alkylamine and a non-reactive group comprising an alkyl group and a hydrogen group surrounding a silicon element. For instance, the first silicon precursor may comprise an organosilane-containing amine group. More specifically, the first silicon precursor may be a at least one of a (Dimethylamino)trimethylsilane, Bis(dimethylamino)dimethylsilane, N,N-dimethyl-2,4,6,8-tetramethyl-cyclotetrasiloxan-2-amine, N,N-diethyl-2,4,6,8-tetramethyl-cyclotetrasiloxan-2-amine, or a combination thereof.

In step 120, a second silicon precursor is supplied into the reactor. The second silicon precursor may adsorb onto the remaining reactive sites which are formed on the surface of the substrate, but not occupied by the first silicon precursor. For instance, the second silicon precursor may adsorb conformally onto the surface along the gap structure.

The second silicon precursor may contain a reactive group comprising an alkylamine and a non-reactive group comprising a hydrogen group surrounding a silicon element. For instance, the second silicon precursor may comprise an aminosilane. More specifically, the second silicon precursor may be at least one of DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; DIPAS, SiH₃N(iPr)₂; 3DMAS, SiH(N(Mc)₂)₃; BEMAS, SiH₂[N(Et)(Me)]₂; TEMS, SiH(NEtMe)₃; TIPAS, SiH(NHiPr)₃; BDIPADS, (N(iPr)₂)SiH₂—SiH₂(N(iPr)₂); BDEADS, (NEt₂)SiH₂—SiH₂(NEt₂); BDPADS, (NPr₂)SiH₂—SiH₂(NPr₂), or a combination thereof.

After the step 120, the film may comprise a silicon precursor layer comprising the first silicon precursor and the second silicon precursor. In step 110 and 120, a non-reactive group of the first silicon precursor and a non-reactive group of the second silicon precursor may not participate in a chemical reaction between the first silicon precursor and the second silicon precursor for forming a silicon precursor layer, resulting in forming a void within the silicon precursor layer. The void generated may lower the k-value of the silicon oxide film. Details of the reaction mechanism will be described later.

In step 130, an oxidant is supplied into the reactor. The oxidant may react chemically with the silicon precursor molecular layers formed in the step 120 to form a silicon oxide film. The oxidant may be an oxygen-containing gas activated by RF power applied to the reactor in-situ or remotely. The oxidant may comprise at least one of oxygen plasma, CO₂ plasma, N₂O plasma, ozone, or a combination thereof.

The steps 100 to 130 to form silicon oxide film may be carried out at about 20° C. and about 100deg. C. or between about 35° C. and about 90° C. and a RF power of about between 30 W and about 200 W or between about 40 W and about 150 W may be applied to dissociate and activate the oxygen-containing gas.

In step 140, whether a target thickness of silicon oxide film is achieved or not is measured. If the target thickness is not achieved, the step 110 to 130 may be repeated. If target thickness is achieved, the next step 140 is carried out. The target thickness may be defined as a set thickness of the film to be formed on the wall of the recess.

The step 110 to 130 may be cyclically repeated a plurality of times. A number of cycles may be input into a control system (e.g., software) of the substrate processing equipment. Whether the target thickness is achieved or not is determined by measuring whether the desired number of cycles is carried out or not. The film growth rate of silicon oxide film formed in steps 110 to 140 may be 0.1 nm per cycle or greater.

Optionally, in step 150, a post treatment may be carried out. The post treatment may remove reaction by-products such as moisture from the silicon oxide film. The post treatment may be carried out by thermal treatment and/or at least one of plasma treatment, UV treatment, VUV treatment (Vacuum UV treatment), or the combination thereof in-situ or ex-situ. In one embodiment, the plasma post treatment may be carried out by supplying at least one of an argon plasma, a helium plasma, a hydrogen plasma, or a combination thereof with RF power of 500 W or less applied at between about 300° C. and about 500° C. or between about 350° C. and about 450° C. In another embodiment, in the plasma post treatment, a high frequency plasma power may be applied to improve a treatment effectiveness (i.e. more moistures may be removed). For instance, a power of 10 MHz or above may be applied.

In step 160, a process may end and the substrate may be unloaded from the reactor. In other embodiment, the steps 110 to 140 and the step 150 may be carried out ex-situ. In other words, the steps 110 to 140 for forming a silicon oxide film may be carried out in one reactor and the step 150 for post treatment may be carried out in another reactor.

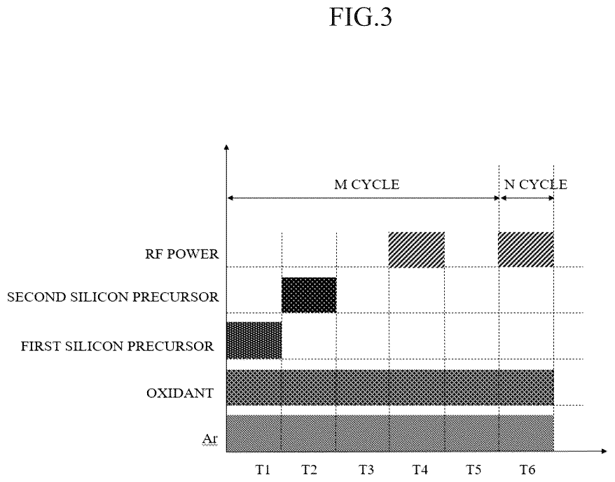

FIG. 3 illustrates a timing graph for the process of FIG. 2. Each step will be described in more detail below.
A step T1 corresponds to the step 110 of FIG. 2 in which the first silicon precursor may be supplied into the reactor.
A step T2 corresponds to the step 120 of FIG. 2 in which the second silicon precursor may be supplied into the reactor. The second silicon precursor may react chemically with the first silicon precursor and form a silicon precursor layer.
A step T4 corresponds to the step 130 of FIG. 2 in which the oxidant is supplied. The oxidant may react chemically with the silicon precursor layer and a silicon oxide film may be formed.
A step T6 corresponds to the step 150 of FIG. 2 in which the post treatment to the silicon oxide film may be carried out. The post treatment may be carried out optionally. The post treatment is to remove a moisture from the silicon oxide film. In one embodiment, a plasma treatment may be carried out as a post treatment.

A purge step may be further carried out after the step T4 and before the step T5, and after the step T5. In another embodiment, a purge step may be carried out after the step T1 and before the step T2.

The steps T1 to T5 may be repeated a plurality of times until the silicon oxide film reaches a target thickness (i.e., a full gapfill) and the step T6 may be repeated a plurality of times.

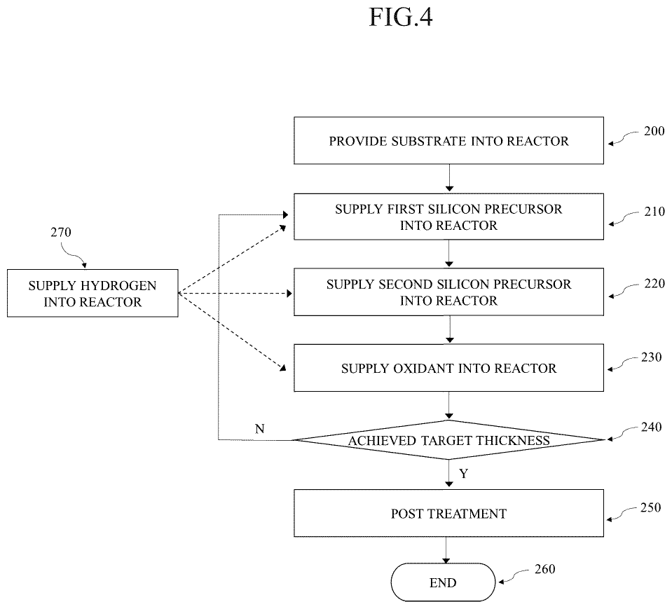

FIG. 4 illustrates another process flow for forming a low-k film using the method.

In FIG. 4, the steps 200 to 260 are the same as FIG. 2 except for the step 270. Therefore, detailed description of the steps 200 to 260 will not be given herein. In FIG. 4, a new step 270 is provided. In step 270, a hydrogen-containing gas is supplied to the reactor throughout the steps 200 to 260. The hydrogen assists a formation of an —OH group as a bonding site along the surface of silicon precursor layer. Therefore, step coverage of the feature and a film growth rate may improve. The hydrogen-containing gas may be at least one of hydrogen, acyclic hydrocarbon, or a combination thereof.

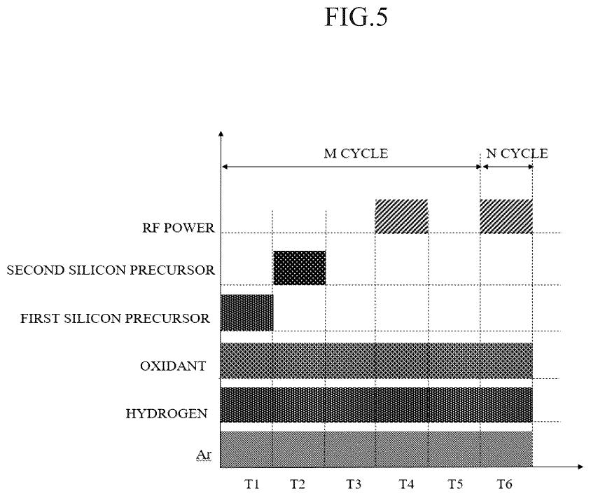

FIG. 5 illustrates a timing graph for the process of FIG. 4.

FIG. 5 is similar to FIG. 3, except for hydrogen is further supplied throughout the process. The hydrogen assists formation of a bonding site such as —OH site along the surface of the silicon precursor layer, resulting in the improvement of the step coverage in a gap structure.

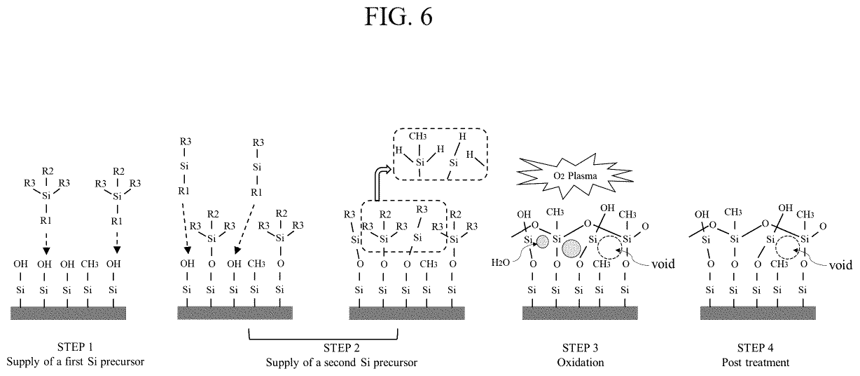

FIG. 6 illustrates a film-forming mechanism in accordance with the method.

In step 1 of FIG. 6, the first silicon precursor may be supplied to the substrate. The first silicon precursor may comprise an organosilane-containing amine group which may contain a reactive group R1 and non-reactive groups R2 and R3. More specifically, the first silicon precursor may be at least one of a (Dimethylamino)trimethylsilane, Bis(dimethylamino)dimethylsilane, N,N-dimethyl-2,4,6,8-tetramethyl-cyclotetrasiloxan-2-amine, N,N-diethyl-2,4,6,8-tetramethyl-cyclotetrasiloxan-2-amine, or a combination thereof.

The reactive group R1 may comprises an alkylamine and the non-reactive group R2 may comprise an alkyl group (e.g., —CH₃) and the non-reactive group R3 may comprise a hydrogen group (e.g. —H) surrounding a silicon element.
In step 1, Si—OH and Si—CH₃ sites are already formed on the substrate from the previous cycle. The reactive group R1 of the first silicon precursor may react with —OH and a Si—O—Si bonding structure may be formed thereon, but not react with —CH₃ and therefore a Si—O—Si bonding structure may not be formed thereon.
In step 2, the second silicon precursor may be supplied to the substrate. The second silicon precursor may comprise an aminosilane which may contain a reactive group R1 and a non-reactive group R3.

The reactive group R1 may comprises an alkylamine and the non-reactive group R3 may comprise a hydrogen group (e.g., —H) surrounding a silicon element.

The reactive group R1 may react with the remaining-OH sites formed on the substrate and a Si—O—Si bonding structure may be formed thereon. However, there may not be a reaction with the non-reactive group R2 (i.e., —CH₃), and therefore, a Si—O—Si bonding structure may not be formed thereon. The space in which a Si—O—Si bonding structure is not formed may become a space resulting in a void later as shown in step 3.
In step 3, an oxidation to the silicon precursor layer may be carried out. The oxidation may be carried out by supplying an oxidant to the reactor. The oxidant may be at least one of oxygen plasma, CO₂ plasma, N₂O plasma, ozone, or a combination thereof. The plasma may be generated by applying a RF power of between about 30 W and about 200 W or between about 40 W and about 150 W to the reactor. By supplying an oxidant, an oxygen element may react with the non-reactive group R3 (i.e., —H) and form a —OH group. The —OH group may react with other-OH group within the film and form a Si—O—Si network structure and leave H₂O as by-products within the film as shown in formula A below.

[—Si—H,H—Si—]+oxidant→-Si—O—Si-+H₂O (A)

On the other hand, the —OH group which may not have other-OH group to react with may remain as —OH sites on the surface of the film as shown in formula B below and act as bonding sites (i.e., reactive sites) for the first silicon precursor in the next cycle.

[—Si—H]+oxidant→-Si—OH (B)

The step 1 to the step 3 may be carried out at 100° C. or below and repeated a plurality of times until the desired film thickness is achieved.

As aforementioned above, after a silicon oxide film is formed, a void is formed in a space in which the non-reactive group R1 (—CH₃) exists and therefore a Si—O—Si bonding structure is not formed. Besides a void, moisture (i.e., H₂O) may be generated as a byproduct in the silicon oxide film according to the formula A above. Therefore, another step may be employed to remove the moisture therefrom.

In step 4, a post treatment may be carried out to remove a moisture from the silicon oxide film. The post treatment may be carried out at high temperature, for instance, at between about 300° C. and about 500° C. or between about 350° C. and about 450° C. to evaporate the moisture. In another embodiment, a plasma may be further provided to remove the moisture more effectively. The plasma may be at least one of an argon plasma, a helium plasma, a hydrogen plasma, or a combination thereof. The plasma may bombard and break the silicon oxide film structure and therefore facilitate the moisture to get out of the film more effectively. The plasma may be generated by applying a RF power of between about 200 W and about 600 W or between about 300 W and about 500 W to the reactor and activate a gas such as argon, helium, hydrogen and the combination thereof.

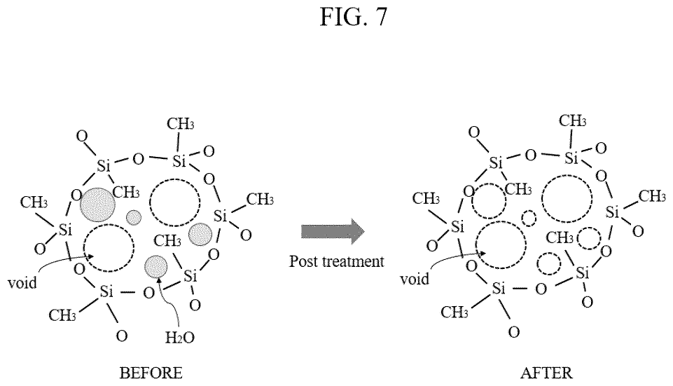

FIG. 7 illustrates a film structure before and after a post treatment. As shown in FIG. 7, after the post treatment, moistures are removed from the film and more voids are formed.

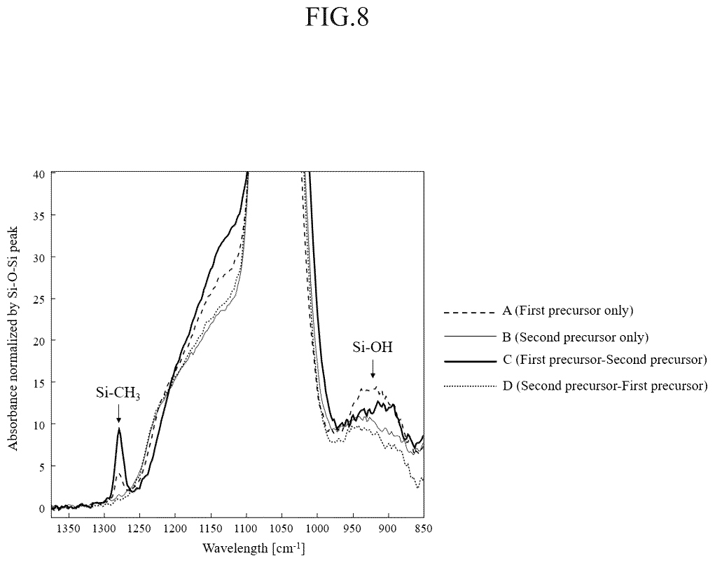

FIG. 8 shows a FT-IR Absorbance graph showing a film composition according to a variety of silicon precursor supply sequence before post treatment.

In FIG. 8, four silicon precursor supply sequences are carried out: supplying only the first silicon precursor A, supplying only the second silicon precursor B, supplying the first silicon precursor, followed by the second silicon precursor C and supplying the second silicon precursor, followed by the first silicon precursor D.

As shown in FIG. 8, referring to the sequence B and the sequence D, the Si—CH₃ peaks (non-reactive group R2) are not detected. In other words, the non-reactive group R2 was not detected at a potential space for forming a void, meaning that the space was filled and no void was formed.

On the other hand, referring to the sequence A and the sequence C, the Si—CH₃ peaks (non-reactive group R2) are detected. In other words, a space in which a void may be formed may be formed and therefore a void may be generated accordingly. More specifically, the sequence C (i.e., supplying the first silicon precursor, followed by the second precursor) shows the highest Si—CH₃ peak intensity. That is, more voids may be generated by the sequence C than by the sequence A. Therefore, there is a technical benefit that a lower k-value may be achieved by employing the sequence C (i.e., supplying the first silicon precursor, followed by the second precursor) as described in the disclosure.

Table 1 shows film properties of SiO₂ film formed according to the disclosure. In Table 1, the silicon oxide film is conformally formed along the surface of the gap structure with a width of 5.2 μm and a depth of 52 μm. The dielectric constant (k-value) is about 3.5, reaching the target k-value of 3.5 or less. As aforementioned, the post treatment removes a moisture from the film and enables more voids to be formed accordingly. Therefore, carrying out the post treatment has a technical benefit of lowering the k-value. The test results show that the step coverage is 94%, achieving the targets.

TABLE 1
Film properties of SiO₂ film formed according to the disclosure

| | Test results | Target |
|---|---|---|
| Dielectric constant (k-value) | ~3.5 | <3.5 |
| Step coverage (%) | 94 | >90 |
| (width 5.2 um, depth 52 um) | | |
| Film growth rate (nm/cycle) | 0.13 | >0.1 |

Table 1 also shows a film growth rate is 0.1 nm or greater. Therefore, supplying dual precursors has a technical benefit of improving a film growth rate and a throughput.

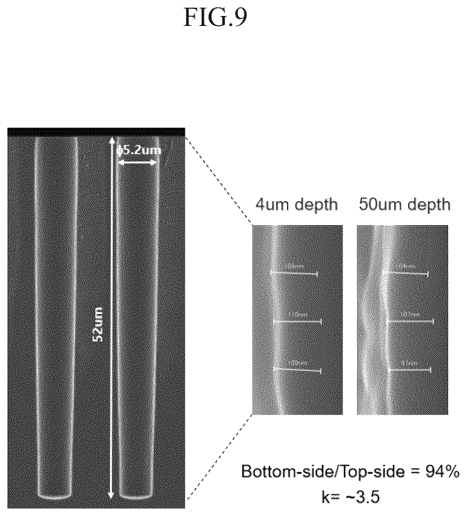

FIG. 9 shows a TEM photo of low-k film formed on the sidewall of the gap using the method.

Referring to FIG. 9, a silicon oxide film is conformally formed on the side wall of the gap by PEALD and then undergoes a post treatment step. A step coverage between top side and bottom side is about 94% and the k-value of 3.42 is obtained, meeting the target ranges.

Table 2 shows a dielectric constant (k-value) of silicon oxide film by at different stages of treatment.

TABLE 2
a dielectric constant (k-value) of silicon oxide film

| | Post treatment condition | k-value |
|---|---|---|
| Condition A | At deposition (w/o post treatment) | >5.0 |
| Condition B | Thermal treatment (390° C., 30 min.) | >5.0 |
| Condition C | Thermal treatment with plasma treatment | ~3.5 |
| | (390° C., Ar plasma, 400 W, 10 min.) | |

As shown in Table 2, a condition A (at deposition, w/o post treatment) results in high k-value (>5.0). The high k-value of condition A may result from moistures existing in the film network structure (FIG. 6 and FIG. 7) since the film is formed at low temperature and low RF power. A condition B (only thermal treatment) also results in high k-value (>5.0). The high-k value of condition B may result from moisture still remaining in the silicon oxide network structure (FIG. 6 and FIG. 7).

A condition C (a thermal treatment and a plasma treatment) results in k-value (˜3.5) that meets the target k-value (3.5 or less). That is, carrying out a thermal treatment and a plasma treatment at the same time may facilitate further to remove moisture from the film network structure and lower the k-value to the target value. In another embodiment, UV or VUV (Vacuum UV) treatment may be carried out instead of plasma treatment.

Table 3 shows a process condition for forming a low-k silicon oxide film according to the disclosure.

TABLE 3
A process condition for forming a low-k silicon oxide film

| Process parameters | | Deposition step | Post treatment step |
|---|---|---|---|
| Temperature(° C.) | Susceptor | 20 to 100 (preferably 35 to | 300 to 500 (preferably 350 |
| | | 90) | to 450) |
| | Showerhead | 30 to 100 (preferably 35 to | 100 to 200 (preferably 120 |
| | | 90) | to 180) |
| | Reactor wall | 30 to 100 (preferably 35 to | 100 to 200 (preferably 120 |
| | | 90) | to 180) |
| Gas flow rate | Source carrier | 50 to 5,000 (preferably 70 to | — |
| (sccm) | Ar | 3,000) | |
| | Purge Ar | 1,000 to 6,000 (preferably | 1,000 to 6,000 (preferably |
| | | 2,000 to 5,000) | 2,000 to 5,000) |
| | Reactant (O2) | 50 to 200 (preferably 70 to | — |
| | | 180) | |
| | Hydrogen | 50 to 3,000 (preferably 70 to | — |
| | (H2) | 2,000) | |
| Process time per | First precursor | 0.1 to 1.0 (preferably 0.2 to | — |
| step (sec) | feeding | 0.8) | |
| | Second | 0.1 to 1.0 (preferably 0.2 to | — |
| | precursor | 0.8) | |
| | feeding | | |
| | Purge | 0.1 to 1.0 (preferably 0.2 to | — |
| | | 0.8) | |
| | RF-ON | 0.05 to 1.0 (preferably 0.1 to | — |
| | | 0.8) | |
| | Post treatment | — | 300 to 1,200 (preferably 400 |
| | | | to 1,000) |

| RF power (W) | 30 to 200 (preferably 40 to | 200 to 600 (preferably 300 |
|---|---|---|
| | 150) | to 500) |
| Process pressure (Pa) | 200 to 500 (preferably 250 | 200 to 500 (preferably 250 |
| | to 450) | to 450) |
| First precursor | Organosilane-containing | — |
| | amine group | |
| Second precursor | Aminosilane | — |

A substrate processing according to the disclosure may be carried out in-situ or cx-situ. For in-situ process, a deposition and a post treatment may be carried out in one reactor. For ex-situ process, a deposition may be carried out in one reactor. After the deposition completes, then the substrate may be transferred to other reactor and the post treatment may be carried out therein.

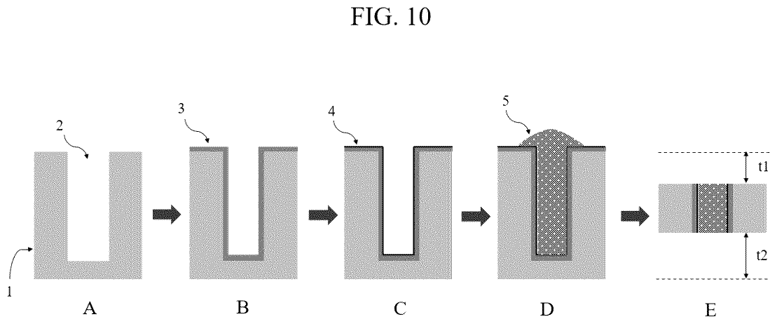

FIG. 10 illustrates a TSV process to which an embodiment of the disclosure may be applied. As illustrated in FIG. 10, the substrate processing method according to the embodiment of the disclosure may be followed by forming a barrier film such as Ta/TaN on the silicon oxide film, filling the recess structure with a conducting film and planarizing the substrate.

In FIG. 10A, a substrate 1 with a recess 2 is provided. The recess may be a gap or a via.

In FIG. 10B, a liner 3 may be formed along the surface of the recess 2. The liner 3 may be a low-k film formed by the method of the disclosure.

In FIG. 10C, a barrier film 4 may be formed on the liner 3. The barrier film may prevent conductive elements of the conducting film 5 to be formed in the next step from diffusing to the substrate 1 through the liner 3. The barrier film 4 may comprise at least one of Ta, TaN, Ta/TaN, and TiN or a mixture thereof. The barrier film may be formed by at least one of ALD, PEALD, CVD, or PECVD.

In FIG. 10D, a conducting film 5 may fill the recess 2. The conducting film 5 may comprise at least one of copper, tungsten and poly-silicon or a mixture thereof. The conducting film 5 may be formed by at least one of Electrochemical deposition or CVD.

In FIG. 10E, a planarization may be carried out. In the planarization, the substrate 1 may be planarized from the top by t1 and be ground from the opposite side of the substrate by t2 (i.e. bottom of the substrate). Although not shown in FIG. 10, in a subsequent process, multiple substrates which were planarized through FIGS. 10A to 10E, may be stacked and therefore form a long and deep recess and a conducting film filling therein.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of forming a film on a wall of a recess of a substrate in a reactor comprising the steps of:
supplying a first silicon precursor to the reactor;
supplying a second silicon precursor to the reactor; and
supplying an oxidant to the reactor;
wherein the first silicon precursor comprises: (1) a reactive group comprising an alkylamine; and (2) a non-reactive group comprising an alkyl group and a hydrogen group;
wherein the second silicon precursor comprises: (1) a reactive group comprising an alkylamine; and (2) a non-reactive group comprising a hydrogen group;
wherein the steps are repeated a plurality of times and a silicon oxide film is formed on the wall of the recess.

2. The method of claim 1, further comprising supplying a hydrogen-containing gas throughout the steps.

3. The method of claim 2, wherein the hydrogen-containing gas comprises at least one of: hydrogen, acyclic hydrocarbon, or a combination thereof.

4. The method of claim 1, further comprising carrying out a post treatment to remove moisture from the silicon oxide film.

5. The method of claim 4, wherein the post treatment is carried out by thermal treatment and at least one of a plasma treatment, a UV treatment, a VUV treatment, or a combination thereof.

6. The method of claim 4, wherein the post treatment comprises a thermal treatment and a plasma treatment by supplying at least one of an argon plasma, a helium plasma, a hydrogen plasma, or a combination thereof.

7. The method of claim 6, wherein the plasma is generated by applying RF power of between about 200 W and about 600 W to the reactor in situ or remotely.

8. The method of claim 7, wherein the plasma is generated by applying RF power of between about 300 W and about 500 W to the reactor in situ or remotely.

9. The method of claim 5, wherein the thermal treatment is carried out at between about 300° C. and about 500° C.

10. The method of claim 9, wherein the thermal treatment is carried out at between about 350° C. and about 450° C.

11. The method of claim 4, wherein the steps for forming a film and the post treatment are carried out in-situ.

12. The method of claim 4, wherein the steps for forming a film and the post treatment are carried out ex-situ.

13. The method of claim 4, wherein a dielectric constant of the silicon oxide film is 3.5 or less.

14. The method of claim 4, wherein a film growth rate of the silicon oxide film is 0.1 nm per cycle or greater.

15. The method of claim 1, wherein the first silicon precursor comprises an organosilane-containing amine group.

16. The method of claim 13, wherein the first silicon precursor comprises at least one of (Dimethylamino)trimethylsilane, Bis(dimethylamino)dimethylsilane, N,N-dimethyl-2,4,6,8-tetramethyl-cyclotetrasiloxan-2-amine, N,N-diethyl-2,4,6,8-tetramethyl-cyclotetrasiloxan-2-amine, or a combination thereof.

17. The method of claim 1, wherein the second silicon precursor comprises an aminosilane.

18. The method of claim 1, wherein the second silicon precursor comprises at least one of: DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; DIPAS, SiH₃N(iPr)₂; 3DMAS, SiH(N(Me)₂)₃; BEMAS, SiH₂[N(Et)(Me)]₂; TEMS, SiH(NEtMe)₃; TIPAS, SiH(NHiPr)₃; BDIPADS, (N(iPr)₂)SiH₂—SiH₂(N(iPr)₂); BDEADS, (NEt₂)SiH₂—SiH₂(NEt₂); BDPADS, (NPr₂)SiH₂—SiH₂(NPr₂), or a combination thereof.

19. The method of claim 1, wherein the oxidant comprises at least one of oxygen plasma, CO₂ plasma, N₂O plasma, ozone, or a combination thereof.

20. The method of claim 19, wherein the plasma is generated by applying a RF power of between about 30 W and about 200 W to the reactor in situ or remotely.

21. The method of claim 20, wherein the plasma is generated by applying a RF power of between about 40 W and about 150 W to the reactor in situ or remotely.

22. The method of claim 1, wherein the method is carried out at between about 20° C. and about 100° C.

23. The method of claim 1, wherein the method is carried out at between about 35° C. and about 90° C.

24. The method of claim 1, wherein a surface of the recess comprises a hydroxyl group (—OH) and an alkyl group.

25. The method of claim 1, further comprising:
forming a barrier film on the silicon oxide film;
filling the recess with a conducting film; and
planarizing the substrate from a top of the substrate,
wherein the barrier layer comprises at least one of Ta, TaN, Ta/TaN, TiN, or a mixture thereof;
wherein the conducting film comprises at least one of copper, tungsten, poly-silicon, or a mixture thereof.
